(19) United States
(12) Patent Application Publication
(10) Pub. No.: US 2026/0259279 A1
(43) Pub. Date: Sep. 3, 2026

(54) ADAPTER AND TEST METER FOR TESTING ELECTRIC VEHICLE SUPPLY EQUIPMENT

(71) Applicant: Megger Instruments Ltd, Dover (GB)

(72) Inventors: Kai Yaw YONG, Dover (GB); Mark HADLEY, Dover (GB); Stanislaw ZUREK, Dover (GB)

(21) Appl. No.: 19/650,962

(22) Filed: Apr. 17, 2026

Related U.S. Application Data
(63) Continuation of application No. PCT/EP2024/079488, filed on Oct. 18, 2024.

(30) Foreign Application Priority Data
Oct. 19, 2023 (GB) 2316000.5

(51) Int. Cl. G01R 31/40; G01R 1/04; G01R 1/20; G01R 27/18

(52) U.S. Cl. CPC G01R 31/40; G01R 1/0416; G01R 1/206; G01R 27/18

(57) ABSTRACT

An adapter for connecting an electrical test meter to electric vehicle supply equipment comprises: a connector having a first, second, third, fourth and fifth electrical contact configured for connection to a vehicle supply connector of the electric vehicle supply equipment; a first, second and third conductor for connection to the electrical test meter; and a switch matrix having respective inputs for the first, second, third, fourth and fifth electrical contacts and respective outputs for the first, second and third conductors for connection to the electrical test meter and a control circuit, the control circuit being configured to set the switch matrix to a switch matrix configuration selected from a plurality of alternative switch matrix configurations, each alternative switch matrix configuration providing a respective connection path to each output, each connection path being from an input to an output.

### CROSS-REFERENCE TO RELATED APPLICATIONS

This application is a continuation under 35 U.S.C. § 120 International Application No. PCT/EP2024/079488, filed October 18, 2024, which claims priority to GB Application No. GB 2316000.5, filed October 19, 2023, under 35 U.S.C. § 119(a). Each of the above-referenced patent applications is incorporated by reference in its entirety.

### TECHNICAL FIELD

The present invention relates generally to an adapter for connecting an electrical test meter to electric vehicle supply equipment, to an electrical test meter configured for connection to the adapter and to test apparatus comprising the adapter and the electrical test meter.

### BACKGROUND

Electric vehicles typically comprise a connector to connect battery charging circuitry, which is typically located on board the vehicle, to an electricity supply external to the vehicle for charging the battery of the vehicle. The electricity supply may be provided by electric vehicle supply equipment (EVSE), which may be, for example, fixed to a wall of a residential building for home charging, or situated at a variety of other locations such as, for example, a workplace, car park, or other charging location. The electric vehicle supply equipment is typically connected to a mains voltage supply and is provided with a connector for connection to the electric vehicle. The electric vehicle supply equipment connector may be at the end of a tethered lead from the electric vehicle supply equipment, for plugging directly into the corresponding connector of the electric vehicle. Alternatively, the electric vehicle supply equipment connector may be fixed to the enclosure of the electric vehicle supply equipment so that a removable lead may be used to connect to the electric vehicle, the removable lead having a suitable connector at each end to connect to the connector of the electric vehicle supply equipment and to the connector of the electric vehicle respectively.

Some types of electric vehicle supply equipment may be configured to provide a single phase supply to the electric vehicle, and other types may provide a three phase supply, or be configurable to supply a one, two and/or three phase supply. The connector of the electric vehicle supply equipment and the corresponding connectors on the vehicle and the removeable lead, if applicable, are provided with sufficient terminals to allow the connection of one, two or three phases in addition to neutral and earth connections. In addition, the connectors are provided with one or more terminals to connect signal lines between the electric vehicle supply equipment and the electric vehicle. In an example, the connector of the electric vehicle supply equipment is provided with five high current capacity contacts, for connection to three live phases, earth and neutral. In addition, two contacts may be provided for signal lines. The one or more signal lines are used to communicate between the electric vehicle supply equipment and the electric vehicle, for example to initiate charging. The connector may be, for example, a Mennekes Type 2 connector having 7 contacts. In some applications, not all the contacts are connected.

In order to test for correct operation of the electric vehicle supply equipment, for example on installation and commissioning, an electrical test meter may be used by an operator to test the electrical characteristics, such as voltage and loop resistance measured between various contacts of the electric vehicle supply equipment connector. An electric test meter is typically provided with three input terminals for use in measuring the electrical parameters. To carry out the tests, the contacts of the electric vehicle supply equipment connector need to be energised, as if an electric vehicle were connected. To achieve this, an adapter is typically connected to the electric vehicle supply equipment connector, which may allow an operator to manually select an appropriate resistance to be applied between one or more control lines and the earth connector to cause the electric vehicle supply equipment to energise the contacts of the connector.

In order to connect the three input terminals of the electrical test meter to the appropriate contacts of the electric vehicle supply equipment for the various tests to be performed, an arrangement of separate connection leads may be attached manually by the operator to make the appropriate connections for each test. The adapter may be used to facilitate connection of the connection leads to the electric vehicle supply equipment connector. The adapter is provided with a suitable connector for connection to the connector of the electric vehicle supply equipment, and provided with terminals, such as sockets for test leads, directly connected to respective contacts of the connector. The connection leads to the meter may be manually attached to the appropriate terminals of the adapter for the test being conducted and the connections are changed manually as appropriate for each test.

### SUMMARY

In accordance with a first aspect, there is provided an adapter for connecting an electrical test meter to electric vehicle supply equipment, the adapter comprising: a connector configured for connection to a vehicle supply connector of the electric vehicle supply equipment, the connector comprising:

a first electrical contact for connection to a first live terminal of the electric vehicle supply equipment; a second electrical contact for connection to a second live terminal of the electric vehicle supply equipment; a third electrical contact for connection to a third live terminal of the electric vehicle supply equipment; a fourth electrical contact for connection to a neutral terminal of the electric vehicle supply equipment; and a fifth electrical contact for connection to an earth terminal of the electric vehicle supply equipment;

a first, second and third conductor for connection to an electrical test meter;

a switch matrix having respective inputs for the first, second, third, fourth and fifth electrical contacts and respective outputs for the first, second and third conductors for connection to an electrical test meter; and

a control circuit, wherein the control circuit is configured to set the switch matrix to a switch matrix configuration selected from a plurality of alternative switch matrix configurations, wherein each alternative switch matrix configuration provides a respective connection path to each output, each connection path being from an input to an output.

This arrangement provides an automated way of connecting the appropriate contacts of the connector of the electric vehicle supply equipment to the appropriate conductors for connection of an electrical test meter, using the control circuit to set the switch matrix to the appropriate switch matrix configuration for each test. This provides a reliable method of performing a variety of tests of the electric vehicle supply equipment, simplifying the procedure for an operator and avoiding operator error. It has been found that the conventional procedure of attaching connection leads between an adapter and a meter and changing the connections as appropriate for each test is cumbersome and prone to error and may be especially difficult in poor lighting conditions.

The control circuit of the switch matrix may be itself controlled by the electrical test meter, which may be programmed to carry out a series of appropriate tests.

In an example, the plurality of alternative switch matrix configurations comprises: a first switch matrix configuration, in which the switch matrix is configured to connect the first electrical contact to the first conductor, the fourth electrical contact to the second conductor and the fifth electrical contact to the third conductor; a second switch matrix configuration, in which the switch matrix is configured to connect the second electrical contact to the first conductor, the fourth electrical contact to the second conductor and the fifth electrical contact to the third conductor; and a third switch matrix configuration, in which the switch matrix is configured to connect the third electrical contact to the first conductor, the fourth electrical contact to the second conductor and the fifth electrical contact to the third conductor.

These configurations allow a series of tests to be performed in which the first, second and third live terminal are successively connected to the third conductor for connection to the electrical test meter, which may be connected to a terminal of the electrical test meter configured to measure a live conductor. The first conductor may be connected to a terminal of the electrical test meter configured to measure an earth conductor and the second conductor may be connected to a terminal of the electrical test meter configured to measure a neutral conductor.

In an example, the plurality of alternative switch matrix configurations comprises a fourth switch matrix configuration, wherein the switch matrix is configured to connect the first electrical contact to the first conductor, the second electrical contact to the second conductor and the third electrical contact to the third conductor.

This configuration allows a measurement by the electrical test meter of the voltages of a three phase supply carried by the first, second and third live terminals.

In an example, the connector comprises a sixth electrical contact for connection to a signal terminal of the electric vehicle supply equipment, and wherein the plurality of alternative switch matrix configurations comprises a fifth switch matrix configuration, wherein the switch matrix is configured to connect the sixth electrical contact to the second conductor and the fifth electrical contact to the third conductor.

This allows the sixth electrical contact, which may be a signal line, to the test meter for tests of the signal line.

In an example, the control circuit is configured to receive a command from the electrical test meter to cause the control circuit to select a switch matrix configuration.

This allows the electrical test meter to set the switch matrix configuration to be appropriate for the tests to be conducted.

In an example, the switch matrix comprises a plurality of electro-mechanical relays configured to be set to the first switch configuration when an actuator of each of the plurality of relays is unpowered.

This provides a default setting of the swich matrix, for a case where the adapter is not provided with power by the test meter, appropriate for a testing a single phase supply. This reduces power consumption for what may be the most frequently used switch configuration.

In an example, the first, second and third conductors for connection to the electrical test meter are configured as a plug arrangement for connection to input sockets on the electrical test meter.

This provides a convenient way to connect the adapter to the electrical test meter. The plug arrangement may be configured to prevent incorrect connection of the conductors of the adapter to the input sockets, that is to say terminals, of the electrical test meter.

In an example, the plug arrangement is configured to mechanically attach the test apparatus to the electrical test meter.

This allows the combination of the adapter and the electrical test meter to be handled more conveniently by the operator.

In an example, the control circuit is configured for galvanic isolation from the electrical test meter, for example by use of an opto-isolator and/or a transformer.

This may provide increased electrical safety.

In an example, the connector comprises a sixth electrical contact for connection to a first signal line of the electric vehicle supply equipment. The control circuit may be configured to control an impedance between the sixth electrical contact and an earth connection.

This allows control circuit to test the operation of the electric vehicle supply equipment in response to a change in impedance.

In an example, the control circuit is configured to measure a duty cycle of a signal coupled from the first signal line.

This allows control circuit to test a signal provided by the electric vehicle supply equipment on the first signal line.

In accordance with a second aspect there is provided an electrical test meter configured for connection to an as claimed comprising one or more processors configured to communicate with the control circuit of the adapter to cause the test meter and adapter to perform a plurality of tests of the electrical vehicle supply equipment comprising tests performed with a plurality of alternative switch matrix configurations, wherein the one or more processors is configured to cause the control circuit to select a respective switch matrix configuration for each of the plurality of tests.

In an example, the plurality of tests comprises a plurality of impedance tests and the test meter is configured to apply an impedance correction for each impedance test that is dependent on the switch matrix configuration. The impedance correction may comprise a predetermined impedance component for each connection path for a switch matrix configuration.

This allows a more accurate measurement of an impedance of a circuit between contacts of the connector of the electric vehicle supply equipment by subtracting a component of impedance introduced by the switch matrix. For example, if a connection path passes through two switch components, such as relays, in series, the impedance may be higher than if the connection path passes through a single switch component. The predetermined impedance component for each connection path is dependent on the connection path.

In accordance with a third aspect, there is provided test apparatus comprising an adapter and a test meter contained within a single enclosure.

This facilitates the handling of the test apparatus by an operator.

Further features and advantages will be apparent from the following description of exemplary embodiments, which are given by way of example only.

### BRIEF DESCRIPTION OF THE DRAWINGS

FIG. 1 is a schematic diagram illustrating an adapter according to the disclosure connected between electric vehicle supply equipment and an electrical test meter;

FIG. 2 is a schematic diagram illustrating an adapter connected between electric vehicle supply equipment and an electrical test meter, showing galvanic isolation between the control circuit of the adapter and the electrical test meter and a processor of the electrical test meter configured to provide a loop impedance correction according to the switch matrix configuration;

FIG. 3 is a schematic diagram illustrating the switch matrix in a first example;

FIG. 4 is a schematic diagram illustrating an adapter connected between electric vehicle supply equipment and an electrical test meter, showing connection of one or more signal lines to the input of the switch matrix;

FIG. 5 is a schematic diagram illustrating the switch matrix in a second example, in which a signal line is provided as an input to the switch matrix;

FIG. 6 is a schematic diagram illustrating the switch matrix in a third example;

FIG. 7 is a schematic diagram illustrating the switch matrix in a fourth example;

FIG. 8 is a schematic diagram illustrating an adapter connected between electric vehicle supply equipment and an electrical test meter, showing an opto-isolator and isolating transformer connected between the electrical test meter and the control circuit of the adapter; and

FIG. 9 is a schematic diagram showing the adapter and electrical test meter contained within a single enclosure.

### DETAILED DESCRIPTION

By way of example, embodiments will now be described in the context of the testing of electric vehicle supply equipment (EVSE) for supplying an alternating current (AC) mains electricity supply to an electric vehicle for charging the battery of the vehicle using a charge circuit in the electric vehicle. The electric vehicle supply equipment may be referred to as a charge point or a charger station. It will be understood that electric vehicle supply equipment may take other forms, for example it may be powered by a generator, and other voltages, either direct current (DC) or alternating current (AC) may be supplied. Other battery-powered equipment, such as home battery systems, may be supplied by a charge point in other examples.

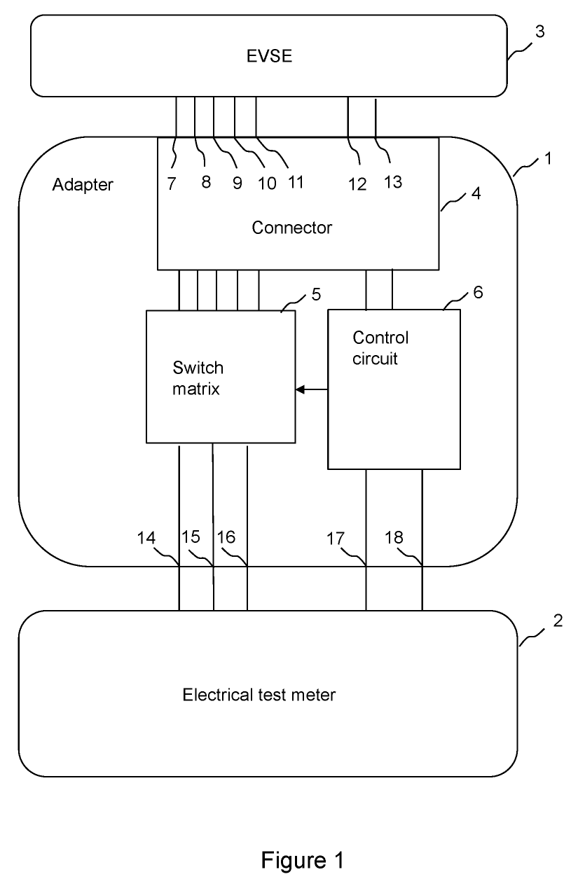

FIG. 1 is a schematic diagram illustrating an adapter 1 according to the disclosure connected between electric vehicle supply equipment 3 and an electrical test meter 2, for testing of the electric vehicle supply equipment, for example on installation. The adapter has a connector 4 for connection with a corresponding connector of the electric vehicle supply equipment. In the example shown, the connector has seven contacts 7-13, comprising an earth E (which may also be referred to as a protective earth PE) and neutral N contact and three live contacts L1, L2, L3, which may provide a three phase power supply, and two signal lines, which may be designated as control pilot (CP) and proximity pilot (PP). In the example described, the electric vehicle supply equipment is configured according to IEC 62196-2. The connector in the example described is a so-called Type 2 connector, which may be referred to as a Mennekes connector. The connector of the electric vehicle supply equipment may be provided as a socket attached to the enclosure of the electric vehicle supply equipment, so that one end of a removable cable can be plugged in to the socket and the other end can be plugged into the socket of an electric vehicle. In this case, the connector 4 of the adapter is a plug for connection with the socket. Alternatively, a cable is provided that is tethered to the electric vehicle supply equipment, so that the connector of the electrical vehicle supply equipment is a plug designed to be plugged into a socket in the electric vehicle. In this case, the connector 4 of the adapter is a socket for connection with the plug of the tethered cable.

As shown in the example of FIG. 1, in the adapter 1, at least five of the contacts of the connector 4, being three live contacts, neutral and earth, are provided as inputs to a swich matrix 5. The switch matrix has three outputs 14, 15, 16, which are provided to three inputs of the electrical test meter test meter 2. The switch matrix may include a permanently connected conductive path between an input and an output in addition to paths which are routed by switches. For example, an earth contact at the input to the switch matrix may be permanently connected to an earth contact at the output of the switch matrix. The switch matrix may include the permanent, hard-wired, connection, which may be anywhere in the adapter, and the switch matrix need not be a separate device having an enclosure, but may be a distributed entity including switches and hard-wired connections. The three inputs of the electrical test meter are provided for connection to appropriate conductors of a circuit under test. According to the test to be performed, the three inputs may be configured in the test meter to be connections for Live, Neutral and Earth conductors of the circuit under test, or may be configured to be connections for first, second and third live conductors for testing a three phase circuit under test. The three inputs may also be configured within the electrical test meter for other tests, for example for measuring a control signal, for example for measuring the duty cycle of a control signal. The switch matrix provides paths between selected inputs from five or more of the contacts of the connector 4 to the three inputs of the electrical test meter, according to the test to be performed.

Examples of sequences of tests of the EVSE include tests for commissioning the EVSE after installation, which may involve several electrical tests performed after energising the EVSE, such as loop impedance test (between Live-Earth, Live-Neutral, or Live-Live conductors), and residual current device RCD tests (Live-Earth) for correct tripping of the circuit breaker if enough current is leaking away (AC or DC). The electrical test meter may, in an example, be a multi-function test meter appropriate for performing the commissioning tests.

The switch matrix 5 is connected to a control circuit 6 which is connected to the electrical test meter by two or more connections 17, 18. In an example, the control circuit 6 may simply comprise energising circuits for electro-mechanical relays in the switch matrix 5, which are directly controlled by the electrical test meter 2. In another example, the control circuit may comprise a processor for controlling the switch matrix, which is in communication with a processor in the electrical test meter 2.

The switch matrix 5 is set to an appropriate switch matrix configuration by the control circuit 6 for each test performed by the electrical test meter 2. In an example, the electrical test meter 2 may be configured to perform a series of tests, for example tests of voltage and/or loop impedance between conductors of the connector of the electric vehicle supply equipment, and the electrical test meter communicates with the control circuit 6 of the adapter to cause the switch matrix 5 to be switched to an appropriate configuration for each test. Each alternative switch matrix configuration provides a connection path to each output, each connection path being from an input to an output.

In an example of a test carried out by the electrical test meter, the switch matrix has a first switch matrix configuration, in which the switch matrix is configured to connect the first electrical contact, for the first live terminal of the EVSE, to the first conductor for connection to the electrical test meter. The fourth electrical contact, for the neutral terminal of the EVSE, is connected to the second conductor for connection to the electrical test meter and the third electrical contact, for the earth terminal of the EVSE, is connected to the to the third conductor for connection to the electrical test meter. The first, second and third conductors are connected, for example by a multi-way plug and socket, to three input terminals of the electrical test meter. The three input terminals of the electrical test meter are configured respectively as inputs to test live, neutral and earth inputs for this test.

In another example of a test carried out, the switch matrix is set to a second switch matrix configuration, in which the switch matrix is configured as in the first switch configuration, except that the second electrical contact, which is the second live connection, is connected to the first conductor for connection to the terminal of the electrical test meter that is configured to test a live connection. In a further example of a test, the switch matrix is set to a third switch matrix configuration, in which the switch matrix is configured as in the first and second switch matrix configuration, except that the third electrical contact, which is the third live connection, is connected to the first conductor.

In a yet further example, all three phases of the supply, that is to say the first, second and third live connections, are connected to respective first, second and third conductors for connection to the three terminals of the electrical test meter. In this case, the three input terminals of the electrical test meter are configured as inputs to test three live inputs. The designation of first, second and third live terminals for three phase connections is arbitrary. In an example, the first conductor for connection to the electrical test meter is for connection to the terminal of the electrical test meter configured for a first live input L1, the second conductor for connection to the electrical test meter is for connection to the terminal of the electrical test meter configured for a second live input L2 and the third conductor for connection to the electrical test meter is for connection to the terminal of the electrical test meter configured for a third live input L3. In another example, the second and third live inputs may be transposed, so that the second conductor for connection to the electrical test meter is for connection to the terminal of the electrical test meter configured for a second live input L2 and the third conductor for connection to the electrical test meter is for connection to the terminal of the electrical test meter configured for a third live input L3.

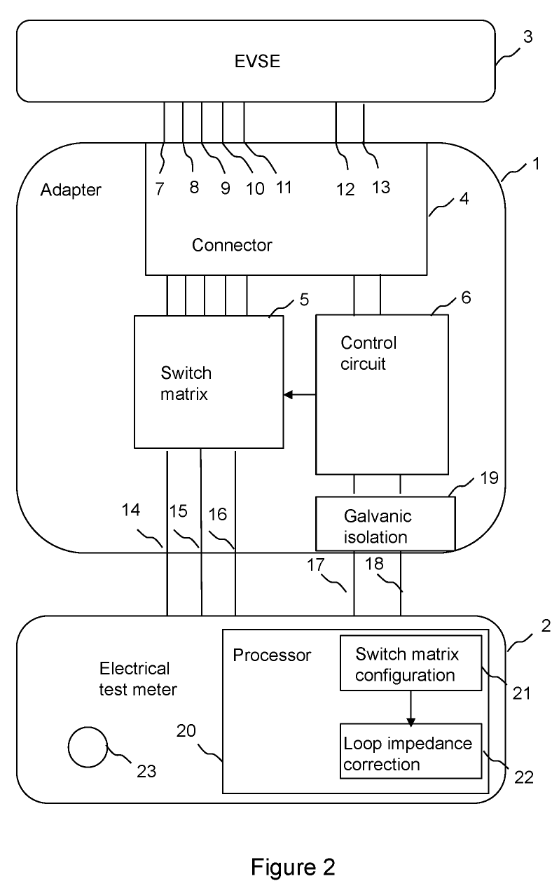

FIG. 2 shows an example having galvanic isolation 19 between the control circuit of the adapter and the electrical test meter, providing isolation for both the power and data connections. In a system employing a reduced number of wires between the adapter and the electrical test meter, two wires 17, 18 may be provided to carry an AC current for the power supply, upon which signalling is superimposed to provide a data connection, so that both the power supply and the data signal can be coupled through an isolating transformer. In another example, an isolating transformer may be used to connect the alternating current (AC) power and a further isolating transformer or an opto-isolator may be used for a data connection. The galvanic isolation of the power and data allows three phase testing, so that the internal ground of the electrical test meter can float with respect to the earth potential, that is to say the potential of the earth wire of the electric vehicle supply equipment connector. This allows the meter to operate without an earth connection. Operation without an earth connection may be required, for example, for testing a three phase supply.

FIG. 2 also illustrates the example where a processor of the electrical test meter is configured to provide a loop impedance correction according to the switch matrix configuration. A processor 20 uses an indication of the switch matrix configuration 21 to select a loop impedance correction 22, which is an impedance value to be subtracted from a measured loop impedance. This corrects a measurement of loop impedance of a circuit for the effect of the resistance of the wiring of the paths to and within the switch matrix and the resistance of the switching devices in the switch matrix, which may be, for example, electro-mechanical relays or semiconductor switches. Measurements of impedance values of each path through the switch matrix for each configuration of the switch matrix may be stored in memory in either the adaptor or the electrical test meter. The appropriate impedance values for a switch configuration may be retrieved from memory by the processor 20 to be used to correct the measured loop impedance value by subtracting the impedance of the appropriate path or paths from the measured loop resistance value. The impedance values may differ between paths through the switch matrix, due, for example, to differing lengths of connecting wire, impedance of connectors and/or the impedance of the switching devices used in each path, which may differ according to the path and/or more than one switching device may be included in series according to the switch matrix configuration. Measurements of impedance values of each path through the switch matrix for each configuration of the switch matrix may be made using a known lead resistance to null out a component impedance, such as a relay contact resistance in the adapter. For example, the adapter may be connected to the test meter, and a lead of known resistance may be connected between two of the electrical contacts of the adapter to which a switch path is selected from the meter. The round trip impedance from the meter via the lead of known resistance may be measured, and from this the combination of the impedances of two of the paths can be calculated. By measuring round trip impedances for several swich positions, the impedance of each path through the switch may be deduced.

In an example, the test meter may detect that an adapter is attached by detecting an electrical or mechanical connection. The type of adapter and/or serial number of the adapter may be indicated by an identifier held in memory in the adapter, for example in memory associated with the control circuit 6, and the test meter may be pre-configured to select an appropriate impedance correction value according to the identifier and the switch matrix configuration, which is set by the electrical test meter according to the test being performed. The impedance correction values may alternatively be held in memory in the adapter, which allows correction values specific to the individual adapter to be entered, for example during a calibration procedure and/or a factory test.

FIG. 2 also illustrates an example in which the electrical test meter is provided with a test button 23 to initiate tests, such as loop impedance tests, using the test meter. The test button 23 comprises a metallic pad galvanically isolated from an operator. For example, a sheet of insulating material may cover the metallic pad and insulate it from the operator. The insulating material protects the operator from receiving an electric shock. The electrical test meter is configured so that when an operator touches and/or presses the galvanically isolated test button 23 to initiate an electrical test by the meter, this causes the electrical test meter to perform an earth potential test to detect whether an elevated earth potential exists in relation to the operator, that is to say to detect that the earth connection of the test meter is at a higher voltage, by more than a predetermined threshold voltage, than the potential of the operator. This may represent a safety hazard, so a warning signal may be activated if an elevated earth connection is detected. The test may be performed by detecting a capacitive coupling to an operator’s finger, through the operator’s body, through the shoes to the ground, permitting a measurement of the potential of internal parts of the instrument with respect to the finger which is assumed to be at the potential of Earth. The test meter may be integrated into the same enclosure as the adapter, so that the safety test is performed for the combination of the adapter and the test meter when connected to the electric vehicle supply equipment.

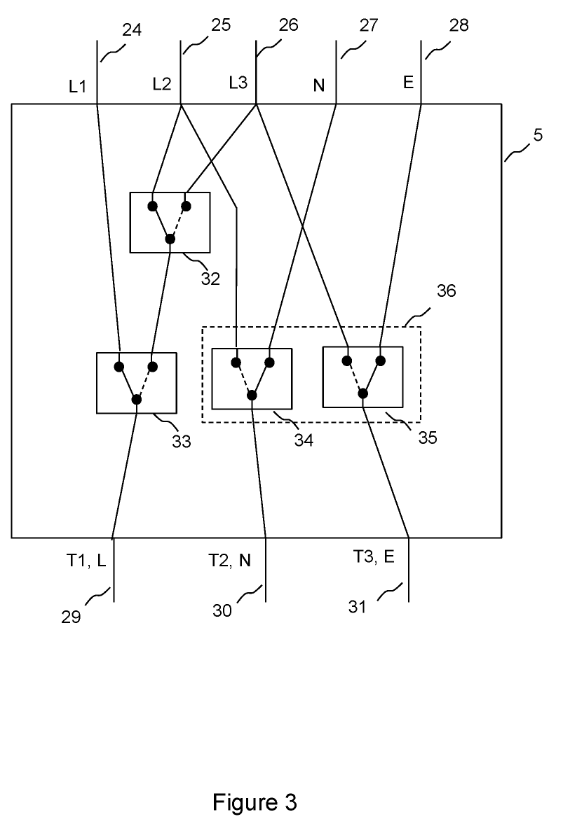

FIG. 3 is a schematic diagram illustrating the switch matrix 5 in an example. Inputs to the switch matrix are shown for a first electrical contact 28 for connection to an earth terminal of the electric vehicle supply equipment, a second electrical contact 27 for connection to a neutral terminal of the electric vehicle supply equipment, a third electrical contact 24 for connection to a first live terminal of the electric vehicle supply equipment, a fourth electrical contact 25 for connection to a second live terminal of the electric vehicle supply equipment and a fifth electrical contact 26 for connection to a third live terminal of the electric vehicle supply equipment. The switch matrix has a first output 29, a second output 30 and a third output 31for a first, second and third conductor for connection to the electrical test meter, which may be connected to a connector for connection to the electrical test meter or may be hard wired to the electrical test meter if the meter and the adapter are provided as a single unit in the same enclosure.

FIG. 3 shows that the paths between the inputs and the outputs in an example may be switched by switching devices, for example electromechanical relays 32, 33, 34, 35. In the example shown, the two relays 34 and 35 are two poles of a double pole double throw relay device 36, in which the two poles are switched by a single control line. For each relay, the solid line in FIG. 3 represents the default state when the relay is not energised and the broken line represents the state when the relay is energised.

As may be seen, in the default state, the electrical contact 24, for the first live connection, is connected to the first conductor 29 for connecting to the first terminal T1 of the electrical test meter by relay 33, the electrical contact 27, for the neutral connection, is connected to the second conductor 30 for connecting to the second terminal T2 of the electrical test meter by relay 34 and the electrical contact 28, for the earth connection, is connected to the third conductor 31 for connecting to the third terminal T3 of the electrical test meter by relay 35. This default configuration corresponds to the first switch matrix configuration. This may be the most used configuration, and so providing this configuration as the default configuration for non-energised relays provides the least power consumption overall. Furthermore, this configuration may be used if the adapter is to be used in an un-powered state for a basic connection to an electrical test meter. Because the relay 33 is set not to select the connection to the relay 32, it does not matter which state is selected in relay 32 for the first switch matrix configuration. By default, relay 32 may be set to the non-energised state.

For the second switch matrix configuration, relay 33 is energised and the other relays are not energised, so that the electrical contact 25, for the second live connection, is connected to the first conductor 29 for connecting to the first terminal T1 of the electrical test meter by relay 33 and 32.

For the third switch matrix configuration, relays 33 and 32 are energised and the other relays are not energised, so that the electrical contact 26, for the third live connection, is connected to the first conductor 29 for connecting to the first terminal T1 of the electrical test meter.

For the fourth switch matrix configuration, relays 34 and 35 are energised and the other relays are not energised, so that the electrical contact 24, for the first live connection, is connected to the first conductor 29 for connecting to the first terminal T1 of the electrical test meter, the electrical contact 25, for the second live connection, is connected to the second conductor 30 for connecting to the second terminal T2 of the electrical test meter, and the electrical contact 26 for the third live connection, is connected to the third conductor 31 for connecting to the third terminal T3 of the electrical test meter.

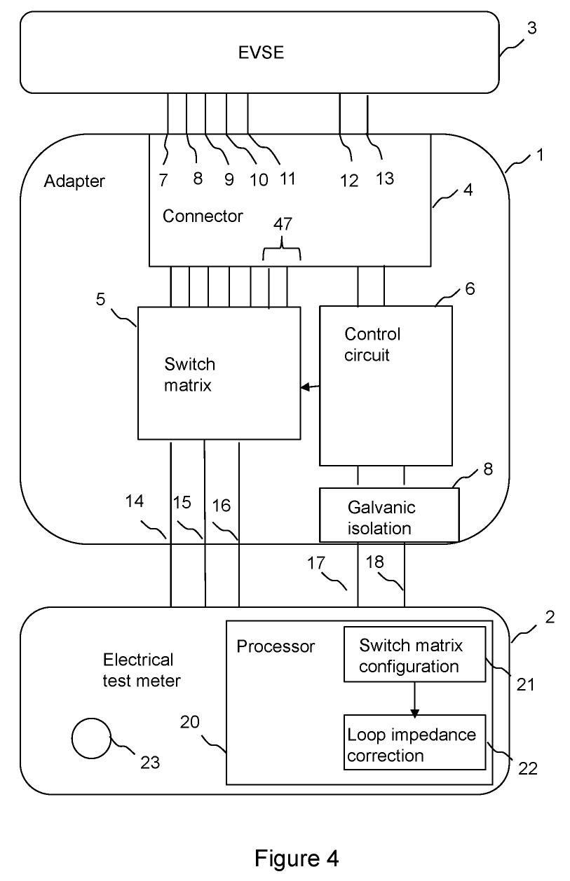

FIG. 4 showing connection of one or more signal lines 47 to the input of the switch matrix 5, allowing the signal lines to be tested by connection of the one or more signal lines to be connected to respective inputs of the test meter.

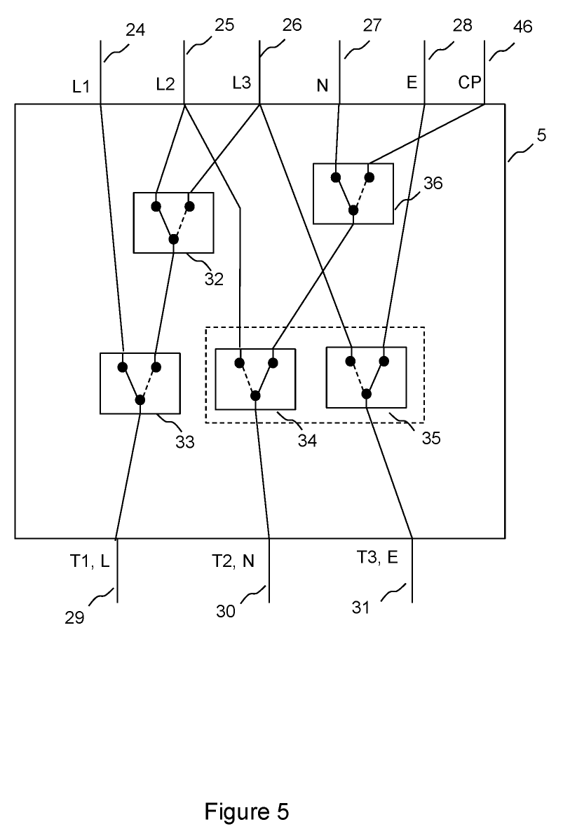

FIG. 5 is a schematic diagram illustrating the switch matrix 5 in an example, in which a signal line, in this case the CP signal line, is provided as a sixth electrical contact 46 as an input to the switch matrix. As shown, the CP signal may be connected by relays 36 and 34 to, in this example, the second conductor 30 for connection to the second terminal of the electrical test meter, and the earth connector, and the fifth electrical contact 28, for the earth connection, is connected by relay 35 to the third terminal of the electrical test meter. This allows testing of the CP signal relative to earth, for example to measure the duty cycle of the CP signal.

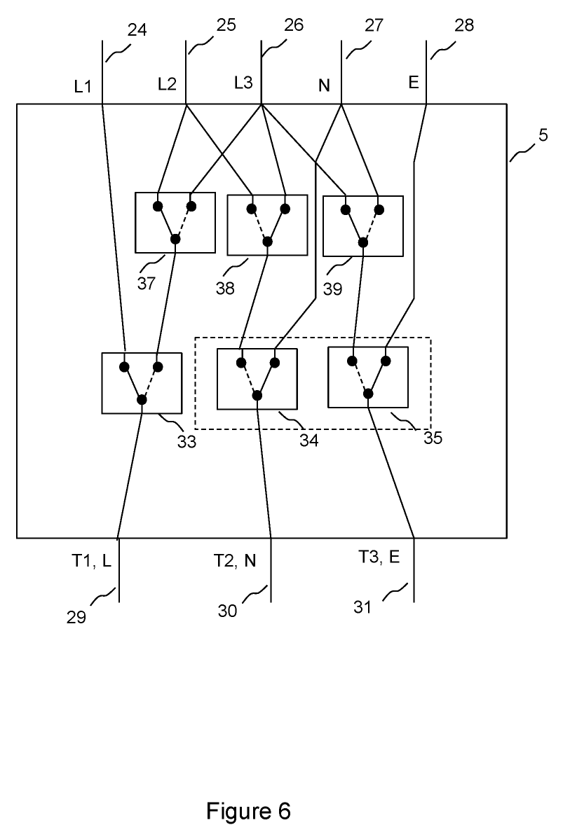

FIG. 6 is a schematic diagram illustrating the switch matrix in a third example, allowing further paths to be selected from the input to the output of the switch matrix 5.

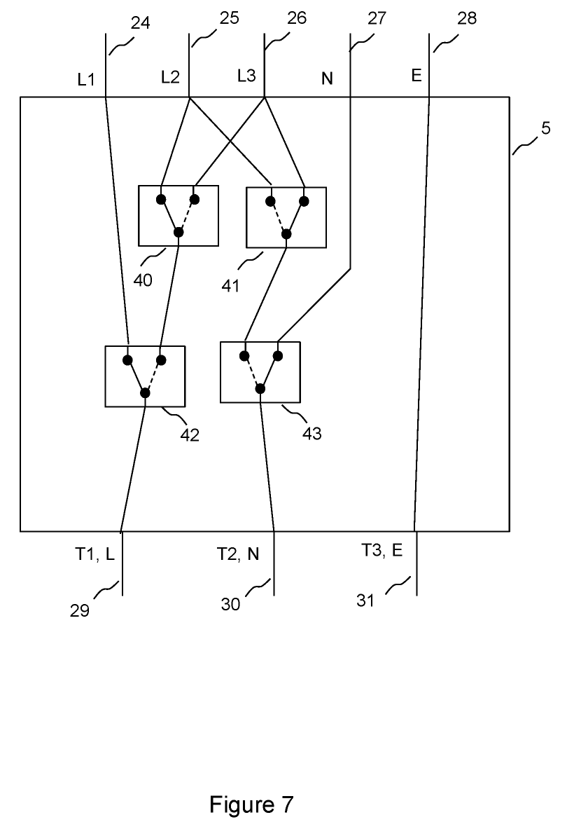

FIG. 7 is a schematic diagram illustrating the switch matrix in a fourth example, in which the fifth conductor 28 for connection of the earth connection is permanently connected to the third conductor 31 for connection to the third terminal of the test meter. This earth connection is logically within the switch matrix, but the physical connection may be, for example, a connection via a conductive chassis or enclosure or any other electrical connection. This allows three phase testing, by allowing testing between each combination of pairs of live terminals L1, L2, L3 in successive tests. This allows three phase testing with an earth connection in place, so that galvanic isolation is not required between the adapter and the electrical test meter.

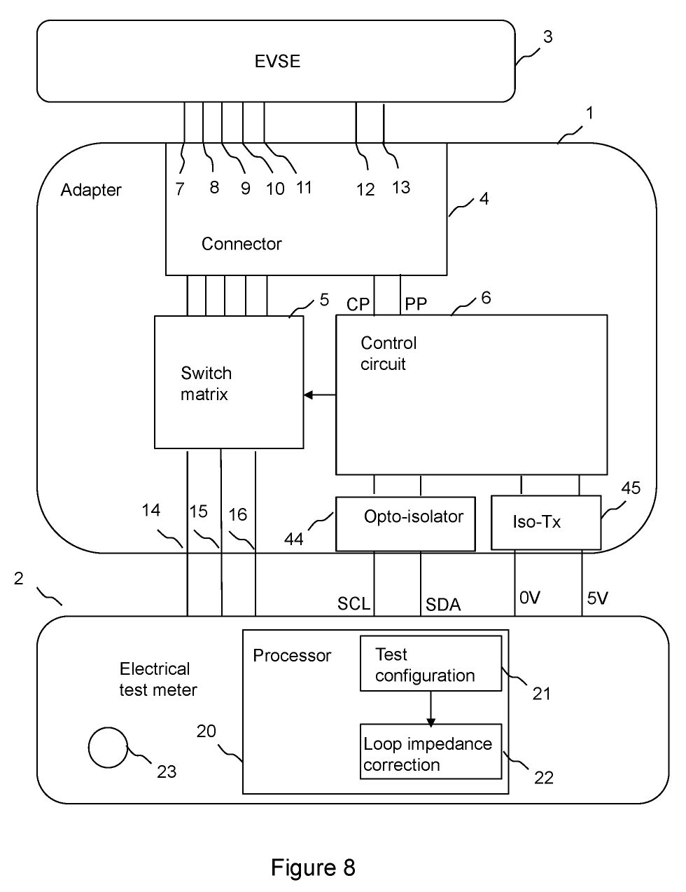

FIG. 8 is a schematic diagram illustrating an adapter connected between electric vehicle supply equipment and an electrical test meter, showing an opto-isolator 44 and isolating transformer 45 connected between the electrical test meter and the control circuit of the adapter. In the example shown, there are two connections, labelled SCL and SDA, between the electrical test meter and opto-isolator 44 of the adapter, and a further two connections carrying 0V and 5V, AC or pulsed, power lines to the isolating transformer 45 of the adapter. In an example, 0V and a positive DC, for example +5V, is connected from the electrical test meter to the adapter and a circuit is provided in the adapter to convert the DC supply into alternating current (AC). The AC is fed to a primary winding of a transformer and the waveform on the secondary winding is rectified to provide a DC supply for the adapter.

The first, second and third conductors 14, 15, 16 of the adapter 1 for connection to the electrical test meter 2 may be configured as a plug arrangement for connection to input sockets on the electrical test meter. The plug arrangement may be arranged mechanically so that it can only be mated with the electrical test meter in the correct configuration. This prevents incorrect connections between the conductors of the adapter and the terminals of the electrical test meter. The plug arrangement may be configured to mechanically attach the test apparatus to the electrical test meter. This provides a more convenient handling of the test meter-adapter combination by an operator.

The control circuit 6 of the adapter may be configured to test and/or control one or more signal lines 12, 13 of the EVSE 3, in an example the CP signal line and/or the PP signal line. The control circuit may be provided with a connection to the appropriate conductors of the connector of the adapter for connection to signal line(s) of the EVSE. The control circuit 6 may have one or more analogue to digital converters, which may digitise the signals and/or voltages seen on the signal lines for analysis using one or more processors of the control circuit 6, to determine whether or not the signals are operating according to the appropriate specification for the EVSE being tested. For example, a duty cycle of a signal on the CP signal line may be measured. The control circuit may also be configured to control an impedance between the CP signal line 12 and an earth connection 11 on the connector 4 of the adapter 1. The control circuit may, for example, control the impedance by controlling the resistance of a field effect transistor (FET), by selecting an appropriate resistor using a relay or other switch, or by other means. The control circuit 6 of the adapter may be under control of one or more processors 20 of the electrical test meter 2, which may determine the test to be conducted and/or a sequence of test steps, and which may receive the test results for the control circuit of the adapter. The test results may be displayed and/or stored on the electrical test meter 2.

In an example, the control circuit may control an impedance between the CP signal line 12 and/or the PP signal line 13 and an earth connection 11 on the connector 4 of the adapter 1 which is expected to cause the EVSE 3 to detect a fault condition. The control circuit may then determine that the EVSE has taken the appropriate action, for example by stopping the supply of a charging voltage, by setting the switch matrix to an appropriate configuration to conduct the test.

In an example, the state of the PP signal line communicates, between the EVSE and the electric vehicle, the maximum current available for charging. An example of a EVSE standard specifies 5 states: NC (not connected), and 13-20-32-63 A. The state is set by an appropriate value of a signal resistor presented between the PP and earth pins of the EVSE connector. When the adapter and test meter are attached to the EVSE instead of an electric vehicle, the adapter provides the appropriate resistance values and may test that the EVSE responds as specified. The CP signal line may require a specific value of a resistor between CP pin and earth to indicate to the EVSE a charging state. According to an EVSE standard, 4 states are specified: A - not connected, B – ready, C – charging without ventilation, D – charging with ventilation. Charging is enabled either in the C or D state, meaning that the power socket in the EVSE is energised as soon as the adapter sets the appropriate resistance for the C or D state. Once the charger socket is energised the appropriate testing with the electrical test meter can be executed, with the switch matrix set to the appropriate configuration to connect the L1, L2, L3, N, E lines to the electrical test meter.

A CP error can be induced by connecting an incorrect resistor, and the electrical test meter may check that the EVSE de-energises, for example by testing a voltage on an appropriate live connector. An earth error can be also induced by the adapter by disconnecting the earth reference from the CP and/or PP signals and checking that the EVSE de-energises, for example by testing a voltage on an appropriate live connector. The forcing of errors by the control circuit 6 of the adapter 1 may be under control of the processor 20 of the electrical test meter 2, which may be configured to perform a sequence of tests of the EVSE 3.

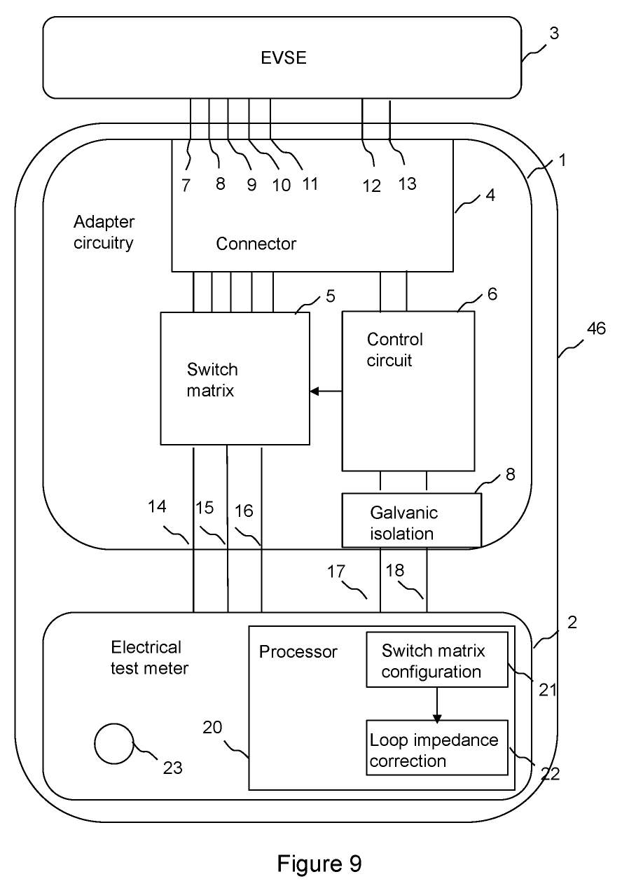

FIG. 9 is a schematic diagram showing the adapter and electrical test meter contained within a single enclosure. The functionality of the adapter and the test meter may be included in the single enclosure, having a connector for connection to electric vehicle supply equipment. This may provide a dedicated test meter for electric vehicle supply equipment.

The above embodiments are to be understood as illustrative examples of the invention. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. An adapter for connecting an electrical test meter to electric vehicle supply equipment, the adapter comprising:
a connector configured for connection to a vehicle supply connector of the electric vehicle supply equipment, the connector comprising:
a first electrical contact for connection to a first live terminal of the electric vehicle supply equipment;
a second electrical contact for connection to a second live terminal of the electric vehicle supply equipment; and
a third electrical contact for connection to a third live terminal of the electric vehicle supply equipment;
a fourth electrical contact for connection to a neutral terminal of the electric vehicle supply equipment;
a fifth electrical contact for connection to an earth terminal of the electric vehicle supply equipment;
a first, second and third conductor for connection to an electrical test meter;
a switch matrix having respective inputs for the first, second, third, fourth and fifth electrical contacts and respective outputs for the first, second and third conductors for connection to an electrical test meter; and
a control circuit, wherein the control circuit is configured to set the switch matrix to a switch matrix configuration selected from a plurality of alternative switch matrix configurations,
wherein each alternative switch matrix configuration provides a respective connection path to each output, each connection path being from an input to an output.

2. An adapter according to claim 1, wherein the plurality of alternative switch matrix configurations comprises:
a first switch matrix configuration, in which the switch matrix is configured to connect the first electrical contact to the first conductor, the fourth electrical contact to the second conductor and the fifth electrical contact to the third conductor;
a second switch matrix configuration, in which the switch matrix is configured to connect the second electrical contact to the first conductor, the fourth electrical contact to the second conductor and the fifth electrical contact to the third conductor; and
a third switch matrix configuration, in which the switch matrix is configured to connect the third electrical contact to the first conductor, the fourth electrical contact to the second conductor and the fifth electrical contact to the third conductor.

3. An adapter according to claim 1, wherein the plurality of alternative switch matrix configurations comprises a fourth switch matrix configuration, wherein the switch matrix is configured to connect the first electrical contact to the first conductor, the second electrical contact to the second conductor and the third electrical contact to the third conductor.

4. An adapter according to claim 1, wherein the connector comprises a sixth electrical contact for connection to a signal terminal of the electric vehicle supply equipment, and wherein the plurality of alternative switch matrix configurations comprises a fifth switch matrix configuration, wherein the switch matrix is configured to connect the sixth electrical contact to the second conductor and the fifth electrical contact to the third conductor.

5. An adapter according to claim 1, wherein the control circuit is configured to receive a command from the electrical test meter to cause the control circuit to select a switch matrix configuration.

6. An adapter according to claim 1, wherein the switch matrix comprises a plurality of electro-mechanical relays configured to be set to the first switch configuration when an actuator of each of the plurality of relays is unpowered.

7. An adapter according to claim 1, wherein the first, second and third conductors for connection to the electrical test meter are configured as a plug arrangement for connection to input sockets on the electrical test meter.

8. An adapter according to claim 7, wherein the plug arrangement is configured to mechanically attach the test apparatus to the electrical test meter.

9. An adapter according to claim 1, wherein the control circuit is configured for galvanic isolation from the electrical test meter.

10. An adapter according to claim 1, wherein the connector plug comprises a sixth electrical contact for connection to a first signal line of the electric vehicle supply equipment.

11. An adapter according to claim 10, wherein the control circuit is configured to control an impedance between the sixth electrical contact and an earth connection.

12. An adapter according to claim 10, wherein the control circuit is configured to measure a duty cycle of a signal coupled from the first signal line.

13. An electrical test meter configured for connection to an adapter according to claim 1 comprising one or more processors configured to communicate with the control circuit of the adapter to cause the test meter and adapter to perform a plurality of tests of the electrical vehicle supply equipment comprising tests performed with a plurality of alternative switch matrix configurations, wherein the one or more processors is configured to cause the control circuit to select a respective switch matrix configuration for each of the plurality of tests.

14. An electrical test meter according to claim 13, wherein the plurality of tests comprises a plurality of impedance tests, and wherein the test meter is configured to apply an impedance correction for each impedance test that is dependent on the switch matrix configuration.

15. An electrical test meter according to claim 14, wherein the impedance correction comprises a predetermined impedance component for each connection path for a switch matrix configuration.

16. An electrical test meter according to claim 15, wherein the predetermined impedance component for each connection path is dependent on the connection path.

17. Test apparatus comprising an adapter according to claim 1 and a test meter according to claim 13, wherein the test apparatus is contained within a single enclosure.17. Test apparatus comprising an adapter according to claim 1 and a test meter according to claim 13, wherein the test apparatus is contained within a single enclosure.
